(19) United States
(12) Patent Application Publication
(10) Pub. No.: US 2022/0158892 A1
(43) Pub. Date: May 19, 2022

(54) TOPOLOGY-DRIVEN BYZANTINE FAULT-TOLERANT CONSENSUS PROTOCOL WITH VOTE AGGREGATION

(71) Applicant: NEC Laboratories Europe GmbH, Heidelberg (DE)

(72) Inventor: Sergey FEDOROV, Heidelberg (DE)

(21) Appl. No.: 17/593,207

(22) PCT Filed: Feb. 19, 2020
(86) PCT No.: PCT/EP2020/054357

§ 371 Date: Sep. 13, 2021

(30) Foreign Application Priority Data
Oct. 14, 2019 (EP) 19203048.4

(51) Int. Cl. H04L 41/0654; H04L 41/12

(52) U.S. Cl. CPC H04L 41/0654; H03K 19/21; H04L 41/12

(57) ABSTRACT

A method for establishing consensus between distributed nodes connected via a data communication network is executed by a leader node. The distributed nodes include active nodes which include the leader node. The method comprises preparing a proposal, constructing a first communication topology and propagating the proposal to the active nodes according to the first communication topology. In case of receiving a sufficient set of vote aggregations from the active nodes, a proposal commitment is created using the vote aggregations and the proposal is accepted. In case of determining that the first communication topology is not reliable to reach consensus on the proposal due to active node faults, an updated communication topology different from the first communication topology is created and the same proposal is continued to be propagated down to the active nodes according to the updated communication topology.

### CROSS REFERENCE TO RELATED APPLICATIONS

This application is a U.S. National Phase application under 35 U.S.C. § 371 of International Application No. PCT/EP2020/054357, filed on Feb. 19, 2020, and claims benefit to European Patent Application No. EP 19203048.4, filed on Oct. 14, 2019. The International Application was published in English on Apr. 22, 2021, as WO 2021/073777 A1 under PCT Article 21(2).

### FIELD

The present invention relates to Byzantine Fault-Tolerant (BFT) consensus protocols and also to distributed ledger technologies. More specifically, the present invention relates to a method for establishing consensus between a plurality of distributed nodes connected via a data communication network, the plurality of distributed nodes including a plurality of active nodes, the plurality of active nodes including a leader node.

### BACKGROUND

Permissioned distributed ledger technologies have recently attracted great attention due to their possible applications in a wide range of industrial use cases. At its core, a distributed ledger system relies on a notion of agreement, or consensus, to ensure consistency of the replicated data. For that purpose, Byzantine fault-tolerant (BFT) voting-based consensus protocols provide desirable properties in terms of resilience and finality of agreement. However, such protocols suffer from high computational and communication overhead.

This motivated researchers and practitioners to devise new BFT consensus protocols that aim at achieving high scalability and performance in practical deployments. For instance, FastBFT protocol (as described in Jian Liu, Wenting Li, Ghassan Karame, N. Asokan: “Scalable Byzantine Consensus via Hardware-assisted Secret Sharing”, in IEEE Transaction on Computers, 2019) is a good example that employs such optimizations as hardware-assisted secret sharing for vote aggregation, combined with passive replication and advanced communication topologies, to achieve high throughput with low latency. As another example, CheapBFT protocol (as described in R. Kapitza, J. Behl, C. Cachin, T. Distler, S. Kuhnle, S. V. Mohammadi, W. Schroder-Preikschat, and K. Stengel: “CheapBFT: resource-efficient byzantine fault tolerance”, in Proceedings of the 7th ACM European conference on Computer Systems, 2012) employs a subset of those optimizations, namely passive replication and trusted hardware assistance.

Known leader-based BFT consensus protocols commonly include a special mechanism, called view change, to handle possible faults of the leader node. In addition, protocols optimized with passive replication typically use another, more conservative, consensus protocol to handle certain non-leader fault scenarios. In that case, a special transition mechanism is invoked to abort the failed consensus round and prepare the system for switching into the fallback protocol.

### SUMMARY

In an embodiment, the present disclosure provides a method for establishing consensus between a plurality of distributed nodes connected via a data communication network. The plurality of distributed nodes include a plurality of active nodes and the plurality of active nodes include a leader node. Each of the plurality of distributed nodes include a processor and computer readable media. The method is executed by the leader node and comprises preparing a proposal, constructing a first communication topology and propagating the proposal to the active nodes according to the first communication topology. In case of receiving a sufficient set of vote aggregations from the active nodes, a proposal commitment is created using the vote aggregations and the proposal is accepted. In case of determining that the first communication topology is not reliable to reach consensus on the proposal due to active node faults, an updated communication topology different from the first communication topology is created and the same proposal is continued to be propagated down to the active nodes according to the updated communication topology.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 is a flow diagram illustrating a processing procedure executed at a leader node according to an embodiment of the invention,

FIG. 2 is a flow diagram illustrating a processing procedure executed at an active node according to an embodiment of the invention,

FIG. 3 is a flow diagram illustrating a processing procedure executed at a passive node according to an embodiment of the invention,

FIG. 4 depicts a network including a plurality of distributed nodes with an optimized communication topology according to an embodiment of the invention, and

FIG. 5 depicts a network including a plurality of distributed nodes with a fallback communication topology according to an embodiment of the invention.

### DETAILED DESCRIPTION

In an embodiment, the present invention improves and further develops a method of the initially described type for establishing consensus between a plurality of distributed nodes in such a way that the implementation complexity is reduced, thereby facilitating verification for correctness.

In an embodiment, the present invention provides a method for establishing consensus between a plurality of distributed nodes connected via a data communication network, the plurality of distributed nodes including a plurality of active nodes, the plurality of active nodes including a leader node, each of the plurality of distributed nodes including a processor and computer readable media. The method includes executing, by the leader node, preparing a proposal; constructing a first communication topology; and propagating the proposal to active nodes according to the first communication topology. The method further includes, by the leader node, in case of receiving any sufficient set of vote aggregations from the active nodes, creating a proposal commitment using the vote aggregations and accepting the proposal, or, in case of suspecting that the first communication topology is not reliable to reach consensus on the proposal due to active node faults, creating an updated communication topology different from the first communication topology and continuing with propagating the same proposal down to active nodes according to the updated communication topology.

According to an embodiment, the present invention provides a computer readable medium having stored thereon instructions for carrying out such a method for establishing consensus between a plurality of distributed nodes connected via a data communication network.

Furthermore, according to an embodiment, the present invention provides a system including a plurality of distributed nodes connected via a data communication network and configured to establish a consensus.

Embodiments of the invention provide a method for establishing consensus between the plurality of distributed nodes by means of a novel Byzantine fault-tolerant consensus protocol that does not require complicated mechanisms to tolerate non-leader faults while employing advanced optimization techniques such as passive replication, advanced communication topologies, and vote aggregation. As an extension to state of art optimized consensus protocols, embodiments of the invention allow to eliminate complicated mechanisms to tolerate non-leader faults, such as fallback and transition sub-protocols, while preserving the same core set of advanced optimization techniques. This allows for a simpler consensus protocol implementation that is easier to verify for correctness, as desired for a critical component of a distributed ledger technology.

According to an embodiment, the present invention relates to a method for topology-driven fault-tolerant consensus with vote aggregation. The method may comprise the step of beginning, by a leader node, a consensus round on a proposal using an optimistic communication topology (which is the first communication topology in the terminology of the present disclosure). The leader node may terminate the consensus round based on the first communication topology. Alternatively, in case of suspected faults of one or more active non-leader nodes, the leader node may switch to an updated communication topology and may resume the consensus round using this new (updated) communication topology. According to an embodiment, the update may include an elimination/replacement of the active nodes from the first communication topology, which were suspected to behave faulty, i.e. the set of active nodes might change when updating the communication topology.

This process, i.e. switching from a current communication topology to an updated communication topology, may be repeated in each case of suspected fault of active non-leader node. According to an embodiment, a threshold specifying a maximum number of allowed repetitions may be applied. The thresholds may be preconfigured or may be determined during operation according to a given algorithm.

Once the threshold is reached, i.e. the leader node has executed the maximum number of consensus rounds with different optimistic communication topologies, the leader node may fall back into using a pessimistic reliable communication topology (which is the fallback communication topology in the terminology of the present disclosure) and resume the consensus round using this fallback communication topology. Basically, this means that in case a given number of optimistic communication topologies are suspected not reliable for reaching consensus, the leader node switches into using a fallback topology. Like in the case of communication topology updates, the set of active nodes might change when switching into a fallback topology. It should be noted that switches into using a fallback topology is in contrast to prior art solutions that, instead of using a fallback topology, perform transitioning into a fallback protocol, which, however, makes the entire process more complicated.

According to an embodiment, active non-leader nodes vote for the leader node's proposal, aggregate received expected valid vote aggregations, if any, with own vote, and communicate the aggregation up, according to the communication topology.

According to an embodiment, the leader node binds the proposal to a vote aggregation and communicates the binding combined with the aggregation to other nodes after aggregated any sufficient quorum of votes. In order to further simplify the protocol, it may be provided that the leader node defers binding of a proposal to an aggregation of votes until after it has aggregated any sufficient quorum of votes. Active and passive nodes may accept a proposal once obtained a valid sufficient vote aggregation as well as a valid binding of the proposal to the aggregation.

Basically, the consensus protocol disclosed herein only improves the handling of faults of non-leader active nodes. Therefore, in accordance with embodiments of the invention, in case of a leader fault, a special mechanism, known as view change, may be implemented to construct a state machine replication protocol.

Recent interest in blockchain technology has given fresh impetus for developing and improving BFT protocols. A blockchain is a key enabler for distributed consensus, serving as a public ledger for digital currencies (e.g., Bitcoin) and other applications. Bitcoin's blockchain relies on the well-known proof-of-work (PoW) mechanism to ensure probabilistic consistency guarantees on the order and correctness of transactions. It is a great success to have PoW regulate the transaction order agreement among thousands of nodes, which cannot be achieved by conventional BFT protocols due to the limitation of the communication complexity. However, Bitcoin's PoW has been severely criticized for its considerable waste of energy and meagre transaction throughput (˜7 transactions per second).

To remedy these limitations, there are several proposals to make the traditional BFT protocols, which are excellent in terms of transaction throughput with dozens of nodes, more scalable to handle consensus for thousands of participating nodes. MinBFT (described in G. S. Veronese, M. Correia, A. Neves Bessani, L. C. Lung and P. Verissimo, “Efficient byzantine fault-tolerance,” in IEEE Transactions on Computers, 2013) and CheapBFT, (described in R. Kapitza, S. Johannes Behl, C. Cachin, T. Distler, S. Kuhnle, S. V. Mohammadi, W. Schröder-Preikschat and K. Stengel, “CheapBFT: resource-efficient byzantine fault tolerance,” in Proceedings of the 7th ACM european conference on Computer Systems, 2012) first propose to use TEE (Trusted Execution Environment) to reduce the total number of peers from 3f+1 to 2f+1, where f is the number of tolerated faulty nodes. However, the communication complexity still remains to be O(n²), which prevents the network from scaling up to hundreds of nodes. Cosi (described in E. Syta, I. Tamas, D. Visher, D. Isaac Wolinsky, P. Jovanovic, L. Gasser, N. Gailly, I. Khoffi and B. Ford, “Keeping authorities” honest or bust” with decentralized witness cosigning,” in Security and Privacy, 2016) leverages tree structure and signature aggregation to reduce the communication complexity to O(n), but using public signature on each node is expensive and the system still requires 3f+1 nodes. FastBFT (described in J. Liu, W. Li, G. O. Karame and N. Asokan, Scalable Byzantine Consensus via Hardware-assisted Secret Sharing, arXiv preprint arXiv:1612.04997, 2016) combines TEE with an efficient message aggregation technique based on secret-sharing to achieve a more efficient protocol using only 2f+1 nodes.

However, the mentioned leader-based BFT consensus protocols commonly invoke rather complicated mechanisms in terms of handling possible faults of non-leader nodes. Embodiments of the invention, applied to certain optimized BFT consensus protocols, contribute to further optimization, in terms of reducing implementation complexity. Being a critical mechanism, consensus protocol implementation will benefit from the reduced complexity, so that it becomes more simple and easier to verify for correctness.

Embodiments of the invention provide a mechanism for a number of distributed computational nodes, connected by a data communication network, to reach consensus on a proposal. The proposal refers, or is bound, to a proposal payload. In one possible embodiment, the payload may represent a sequence of transactions to be added to a distributed ledger. In another possible embodiment, the payload may represent a sequence of operations to be performed by a replicated state machine.

According to embodiments, the plurality of distributed nodes connected via a data communication network are supposed to execute a common piece of algorithm, called consensus algorithm. Those nodes that are correctly executing the consensus algorithm are called correct nodes. The remaining nodes are called faulty nodes. The number of faulty node is assumed to have a known upper bound. The consensus is established among correct nodes by agreeing on and accepting the proposal, according to the algorithm.

In some embodiments, a node can be provided with a trusted execution environment (TEE). Herein, a TEE is defined as an isolated computational environment, together with strictly defined mechanisms to interact with it. TEE provides a certain level of guarantee for correct execution of the code running within the TEE, preserving the code's integrity as well as integrity and confidentiality of the data processed by the code. An isolated instance of such protected code and data is referred to herein as trusted application.

In different embodiments, depending on the desired level of isolation, TEE can be provided by a dedicated hardware device (e.g. Trusted Platform Module), CPU feature (e.g. Intel® SGX or ARM TrustZone), virtualization technology (e.g. XEN or KVM), OS kernel (e.g. Linux Containers or OS processes), or even purely in application software (e.g. using secure modular programming techniques).

According to embodiments of the invention, the proposal is prepared by a designated node called the leader node. The proposal may include a unique proposal identifier that distinguishes it from any other proposal.

According to embodiments of the invention, the leader node selects a subset of nodes according to a predefined algorithm, e.g. randomly. The leader node together with the selected nodes are called active nodes. The additional nodes are called passive nodes. Active non-leader nodes can vote for the proposal to be accepted. The vote refers, or is bound, to the corresponding proposal identifier. The votes that are bound to the same proposal identifier can be combined, or aggregated, into a more compact representation called (partial) vote aggregation. For convenience, a single vote can be considered as a simple vote aggregation solely consisting of that vote.

According to embodiments, once the leader node has collected a set of vote aggregations that represents a sufficient number of votes produced by different active nodes, it obtains a commitment vote aggregation by further aggregating the collected vote aggregations. Then the leader node binds the corresponding proposal to the commitment vote aggregation to obtain a commitment binding. After that, the leader node creates a proposal commitment that includes the commitment binding together with the corresponding vote aggregation. Given a valid proposal commitment, active and passive nodes can safely accept the corresponding proposal.

Applied to a BFT consensus protocol optimized with passive replication and optimistic communication topology, embodiment of the invention allows to resume a consensus round, interrupted due to a suspected active node fault, with an updated communication topology. Falling back to using a pessimistic, but reliable, communication topology eliminates the need for a distinct fallback protocol.

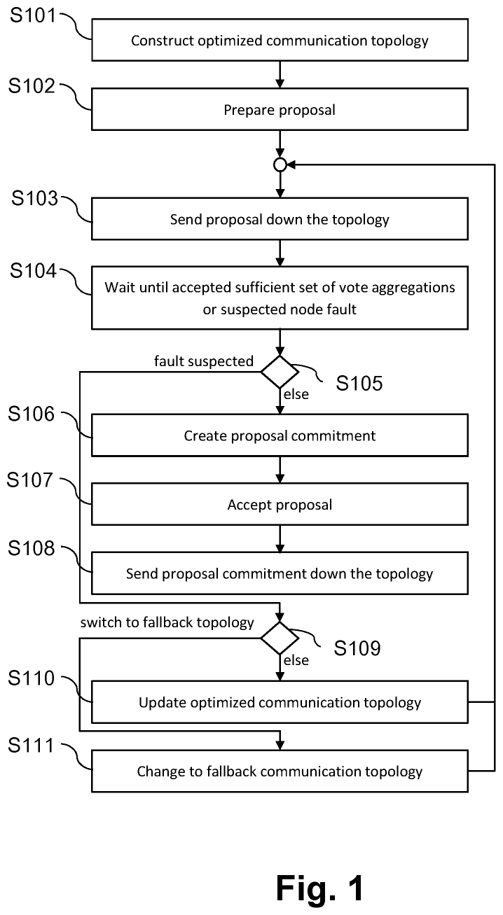

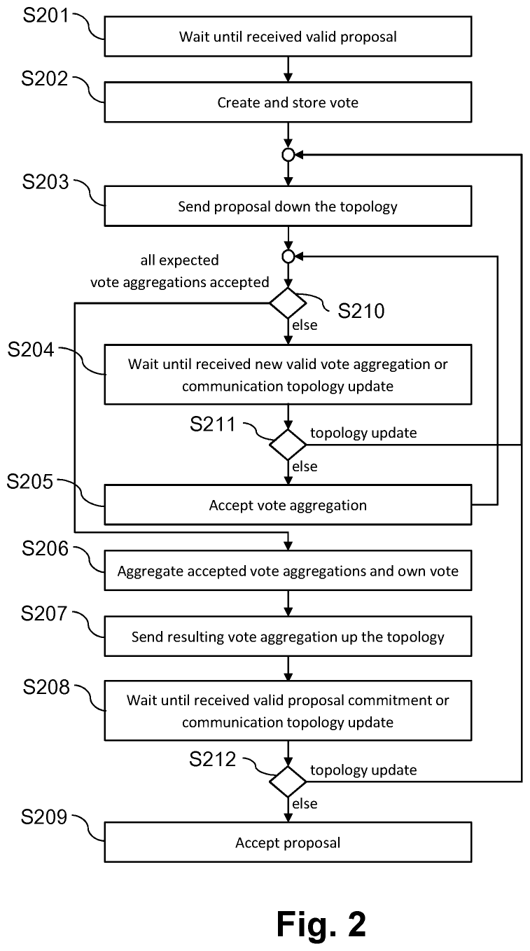

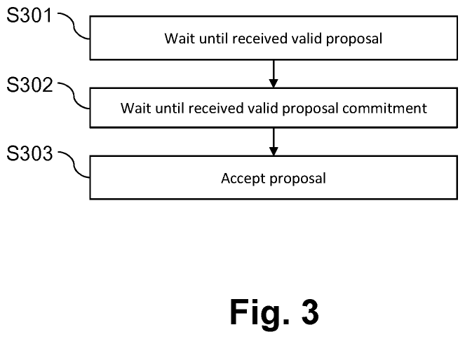

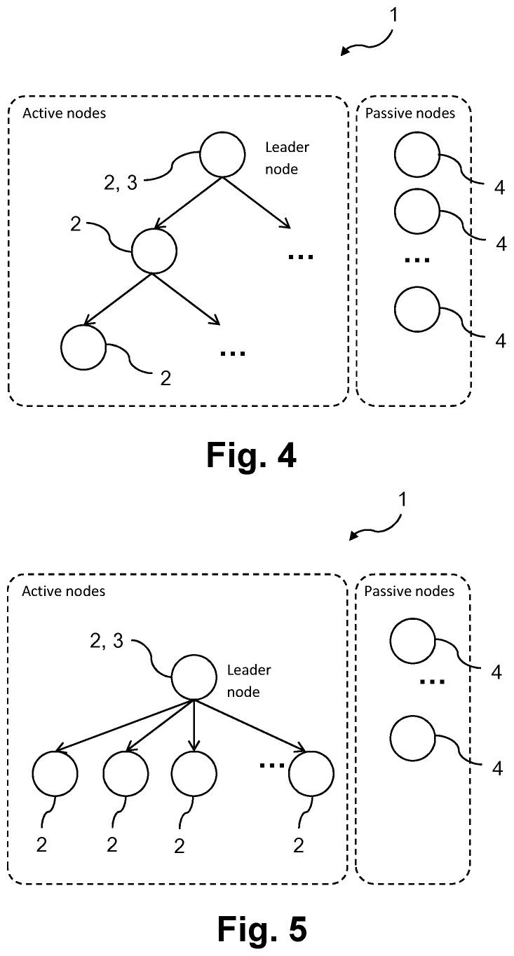

FIGS. 1, 2 and 3 are flow diagrams illustrating a processing procedure for establishing consensus between a plurality of distributed nodes according to an embodiment of the invention. The processing executed at a leader node is shown at FIG. 1, while the processing executed at any non-leader active node and at any passive node, respectively, is shown at FIG. 2 and at FIG. 3, respectively. Generally, the procedure may be executed in a network as exemplarily depicted in FIG. 4. According to this embodiment, the network 1 includes a number of nodes in which a subset thereof are active nodes 2. One of the active nodes is selected to be a leader node 3. The remaining nodes are passive nodes 4.

As shown at S101, the leader node 1 constructs an optimized communication topology, according to a predefined algorithm. A possible optimized communication topology according to an embodiment of the invention is the one of the network depicted in FIG. 4 having a tree structure. The optimized communication topology is constructed as a first communication topology that is utilized to start a first round of the consensus protocol.

As shown at S102, the leader node 1 prepares a new proposal by binding a new proposal identifier to a proposal payload. It should be noted that binding of the identifier to an expected commitment vote aggregation is deferred to a later step (see step S106 below).

As shown at S103, the leader node 1 propagates the proposal down to other nodes 2 according to the communication topology. From the perspective of an active node 2, this corresponds to waiting for a valid proposal, as shown at S201 in FIG. 2. Upon receiving a new proposal, an active node 2 verifies if the proposal should be accepted. If the check fails, the active node 2 does not execute any of the following steps. On the other hand, if the check is successful, the active node 2 produces a vote bound to the proposal identifier, stores the vote in memory, and propagates the proposal down to other nodes according to the topology, as shown at S202 and S203 in FIG. 2.

Next, as shown at S204, the active node 2 waits for receiving valid vote aggregations from other nodes of the topology. When the active node 2 receives a vote aggregation from another active node 2 according to the topology, it verifies if the vote aggregation is valid, then accepts the valid aggregation, as shown at S205. This continues until the active node 2 determines at S210 that it has accepted an expected set of valid aggregations.

Once an active non-leader node 2 has accepted an expected set of valid vote aggregations (possibly none) according to the topology, it further aggregates the collected votes together with its own vote, as shown at S206, then propagates the resulting aggregation up to another active node 2 according to the topology, as shown at S207.

Turning back to FIG. 1, once the leader node 3 has accepted any sufficient set of valid vote aggregations at S104 and no active node faults have been determined at S105, the leader node 3 creates a proposal commitment using the vote aggregations at S106 and accepts the proposal at S107. Furthermore, as shown at S108, the leader node 3 propagates the proposal commitment down to other nodes according to the communication topology.

As shown at S208 in FIG. 2, when an active node 2 receives the proposal commitment, it verifies if the included commitment vote aggregation and commitment binding are both valid, then accepts the corresponding proposal at S209.

According to an embodiment of the invention, the leader node 3 may suspect that the topology constructed as the first communication topology may not be reliable to reach consensus due to node faults. Such determination may be made at S105 in FIG. 1. In this case, the leader node 3 constructs an updated second communication topology, different from the first communication topology, as a new optimized communication topology, according to a predefined algorithm, as shown at S110. Then, at least for the changed parts of the topology, the leader node 3 invokes the method execution starting from step S103 using the updated second communication topology and the same proposal (unless switching to a fallback topology, as described in further detail below).

In case it is suspected, at S105, that also the second optimized topology may not be reliable to reach consensus due to some pattern of node faults, the leader node 2 may decide at S109 whether to try another optimized communication topology (different from the first and from the second communication topologies) or to construct a fallback topology. In the latter case, the leader node 2 invokes the method execution starting from S103 using the fallback topology and the same proposal. In a fallback topology, the leader node 3 communicates directly to a number of active leaf nodes that is sufficient for collecting enough votes to form a proposal commitment in case of any assumed number of faulty non-leader active nodes. A possible fallback topology is shown in FIG. 5.

Regarding the activity of an active node 2 it can be noted that a topology update decided by the leader node 3 may occur either when the active node 2 waits for receiving new valid vote aggregations, as shown at S204, or when the active node 2 waits for receiving a valid proposal commitment, as shown at S208. In both cases the active node 2 aborts the regular process as described above and continues, as shown at S211 and S212, respectively, with sending the current proposal down the new communication topology, as shown at S203, i.e. at least for the changed parts of the topology.

The activity of a passive node 4 is exemplarily illustrated in FIG. 3. This activity is rather restricted and just includes the steps of waiting for receiving a valid proposal, as shown at S301 in FIG. 3, and waiting for receiving a valid proposal commitment, as shown at S302. If both are successfully received, the passive node 4 accepts the proposal at S303.

In one embodiment, the communication topology resembles a balanced tree, rooted in the leader node, wherein a node of the tree represents a computing node, and an edge of the tree represents a communication path. In case an active node is suspected to be faulty, the tree is updated by replacing the suspected node with a passive node, and moving the node that signaled the potential fault to a leaf position.

In one embodiment, each active node is provided with TEE and executes a trusted application. The leader node utilizes the trusted application to assign (bind) unique identifiers to proposals. In a further embodiment, the proposal identifiers are obtained from a monotonic counter.

In a further embodiment, active nodes utilize the trusted application to produce their votes for a valid proposal.

In one further embodiment, the votes are represented as binary numerals, called secret shares. In one further embodiment, a vote (partial) aggregation is obtained with bitwise XOR operation on the corresponding secret shares. In another further embodiment, a vote (partial) aggregation is obtained with a cryptographic hash function applied to a concatenation of the corresponding secret shares and/or vote aggregations.

In a further embodiment, a secret share is randomly generated for each non-leader active node and proposal identifier by the trusted application. In another further embodiment, a secret share is derived by the trusted application with a key derivation function from a secret key value using the corresponding proposal identifier. In one further embodiment, the secret key is generated for each non-leader active node by the trusted application. In another further embodiment, the secret key of each non-leader active node is itself derived by the trusted application with a key derivation function from a common secret key which is generated by the trusted application. In another further embodiment, the two-step key derivation is combined into a single-step key derivation.

In another further embodiment, the votes and vote aggregations are represented as digital signatures or message authentication codes produced by the trusted application over at least parts of the corresponding proposal.

In a further embodiment, the nodes utilize the trusted application to verify if a vote aggregation is valid. In a further embodiment, the nodes utilize the trusted application to certify a valid vote aggregation so that such certificate can be verified by a computing device that is not provided with TEE. Such vote aggregation certificate produced by the leader node acts as a binding of the proposal identifier to the aggregation. In a further embodiment, the vote aggregation certificate is represented as a digital signature or a message authentication code produced by the trusted application over at least parts of the corresponding proposal. In a further embodiment, the vote aggregation certificate signature or message authentication code also covers a cryptographic digest of the corresponding vote aggregation.

Many modifications and other embodiments of the invention set forth herein will come to mind to the one skilled in the art to which the invention pertains having the benefit of the teachings presented in the foregoing description and the associated drawings. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A method for establishing consensus between a plurality of distributed nodes connected via a data communication network, the plurality of distributed nodes including a plurality of active nodes, the plurality of active nodes including a leader node, each of the plurality of distributed nodes including a processor and computer readable media, the method comprising executing, by the leader node, the following steps:
preparing a proposal;
constructing a first communication topology;
propagating the proposal to the active nodes according to the first communication topology; and
in case of receiving a sufficient set of vote aggregations from the active nodes, creating a proposal commitment using the vote aggregations and accepting the proposal, or
in case of determining that the first communication topology is not reliable to reach consensus on the proposal due to active node faults, creating an updated communication topology different from the first communication topology and continuing with propagating the same proposal down to the active nodes according to the updated communication topology.

2. The method according to claim 1, further comprising:
constructing, by the leader node after having determined that the updated communication topology not reliable to reach consensus on the proposal due to active node faults, a fallback communication topology, and
continuing with propagating the same proposal down to active nodes according to the fallback communication topology.

3. The method according to claim 2, wherein the fallback communication topology includes a number of the active nodes being active leaf nodes, and wherein the leader node, when utilizing the fallback topology, communicates directly to a number of the active leaf nodes that is sufficient for collecting enough votes to form a proposal commitment in case of an assumed number of faulty non-leader active nodes.

4. The method according to claim 1, further comprising:
deferring, by the leader node, a creation of a commitment binding that includes binding of a proposal to an aggregation of votes of active nodes until after the leader node has aggregated a sufficient quorum of votes to reach consensus on the proposal.

5. The method according to claim 1, wherein the proposal commitment includes a commitment binding together with a corresponding commitment vote aggregation.

6. The method according to claim 1, further comprising:
receiving, by a first one of the active nodes, the proposal commitment;
verifying, by the first one of the active nodes, a commitment vote aggregation and a commitment binding of the proposal commitment; and
accepting, by the first one of the active nodes, the proposal in case the verifying step determined that both the commitment vote aggregation and the commitment binding are valid.

7. The method according to claim 1, wherein constructing the first communication topology or the updated communication topology comprises organizing, by the leader node, the active nodes into a tree structure, which is rooted in the leader node.

8. The method according to claim 1, wherein creating the updated communication topology comprises updating a tree structure of the first communication topology by replacing suspected ones of the active nodes of the respective previous updated communication topology with passive nodes and moving the suspected active nodes to leaf positons of the tree structure.

9. The method according to claim 1, wherein the leader node utilizes a trusted application executed within a trusted execution environment, of the leader node to bind proposal identifiers to proposal payloads.

10. The method according to claim 1, further comprising:
executing, by a first one of the active nodes, a trusted application running in a trusted execution environment of the first one of the active nodes, and
utilizing, by the first one of the active nodes, the trusted application to produce a vote of the first one of the active nodes for a valid proposal.

11. The method according to claim 1, wherein votes are represented as binary numerals utilized as secret shares.

12. The method according to claim 11, wherein a vote aggregation or a vote partial aggregation is obtained by applying bitwise XOR operation on the corresponding secret shares, and/or wherein a vote aggregation or a vote partial aggregation is obtained by applying a cryptographic hash function to a concatenation of the corresponding secret shares.

13. The method according to claim 11, wherein one of the secret shares is randomly generated for each non-leader active node and proposal identifier by a trusted application, and/or wherein one of the secret shares is derived by the trusted application with a key derivation function from a secret key value using the corresponding proposal identifier.

14. The method according to claim 1, wherein votes and/or vote aggregations are represented as digital signatures or message authentication codes produced by a trusted application over at least parts of the corresponding proposal.

15. A computer readable medium comprising instructions for carrying out a method for establishing consensus between a plurality of distributed nodes connected via a data communication network, the plurality of distributed nodes including a plurality of active nodes, the plurality of active nodes including a leader node, each of the plurality of distributed nodes including a processor and computer readable media, the method comprising:
preparing a proposal;
constructing a first communication topology;
propagating the proposal to the active nodes according to the first communication topology; and
in case of accepting a sufficient set of vote aggregations from the active nodes, creating a proposal commitment using the vote aggregations and accepting the proposal, or
in case of determining that the first communication topology is not reliable to reach consensus on the proposal due to active node faults, creating an updated communication topology different from the first communication topology and continuing with propagating the same proposal down to the active nodes according to the updated communication topology.
